(19) United States
(12) Patent Application Publication
(10) Pub. No.: US 2006/0255901 A1
(43) Pub. Date: Nov. 16, 2006

(54) Production of microelectromechanical systems (mems) using the high-temperature silicon fusion bonding of wafers

(76) Inventor: Uwe Schwarz, Erfurt-Niedernissa (DE)

Correspondence Address: DUANE MORRIS, LLP;IP DEPARTMENT, 30 SOUTH 17TH STREET, PHILADELPHIA, PA, 19103-4196, US

(21) Appl. No.: 10/537,211

(22) PCT Filed: Dec. 5, 2003
(86) PCT No.: PCT/DE03/04015

§ 371 Date: Mar. 20, 2006

(30) Foreign Application Priority Data
Dec. 5, 2002 (DE) 102 57 097.3

(51) Int. Cl. G01L 1/22; H01L 21/302; H01L 27/10

(52) U.S. Cl. 338/4; 257/204; 438/199; 438/459; 438/691

(57) ABSTRACT

The invention relates to a method for manufacturing MEMS devices, in which the sensor and the electronics for processing the sensor signal are monolithically integrated.

### BACKGROUND OF THE INVENTION

The invention relates to a method for manufacturing MEMS devices, in which the sensor and the electronics for processing the sensor signal are monolithically integrated.

### BRIEF SUMMARY OF THE INVENTION

MEMS devices have been manufactured for years on the basis of silicon technologies. Initially, sensor elements have been denoted as MEMS devices, which are composed of a micromechanical portion and a microelectronic portion. The production methods may be divided into two categories according to their micromechanical configuration. On the one hand, a silicon wafer is processed in its total vertical dimension, i.e., it is processed into its depth direction to manufacture structures for the detection of mechanical entities, such as pressure and acceleration (bulk micromachining technologies). On the other hand, such structures are only created at the surface of the silicon wafer (surface micromachining technologies). The method according to the present invention represents a combination of both types of technologies.

While initially the sensors for the detection of mechanical parameters and the signal processing electronics (for instance, digital integrated circuits) have been provided as separate entities, the advance in technology calls for the monolithic integration of both components. The integration of micromechanical sensors and electronic circuits in a single chip is demanding with respect to the manufacturing technology, since the manufacturing processes for the sensors are frequently not compatible with the highly integrated CMOS technologies having feature sizes of ≦1μ. A compromise with respect to achievable performance characteristics (sensitivity, precision, measurement range), integration (feature sizes), reliability and manufacturing cost is necessary.

The specific methodology known for the part of the micromechanical sensors of MEMS devices comprises the patterning of a cavity body, frequently a cavity wafer, by well-established semiconductor process steps, such as oxidation, photolithography, and wet chemical etch processes. In this way, recesses or depressions are etched into the silicon, which are formed into cavities by covering the same in a later manufacturing stage, wherein the silicon membrane or any other sensor elements that are moveable upon mechanical stress are located above the cavities. After the patterning of the cavity body, it is non-separably bonded to a top cap wafer by means of a wafer bond technique with that side that has formed therein the recesses, so that cavities are formed around the recesses. Thereafter, the wafer stack formed in this manner is processed by silicon grinding and polishing processes, as are well-established in semiconductor processing, thereby significantly thinning the top cap wafer.

DE-A 199 27 970 and DE-A 199 27 971 disclose an intermediate layer deposited on one of the two semiconductor wafers for the formation of cavities. Recesses (depressions) are then formed in the intermediate layer. By means of the intermediate layer, the semiconductor wafer is bonded to a second semiconductor wafer. Thereafter, one of the two semiconductor wafers is thinned to a thickness corresponding to the thickness of the membrane, thereby forming a membrane above the cavity. Since in these instances, the electronic structure is formed in the homogeneously doped wafer material, and since the wafers are connected by means of an intermediate layer formed on one of the semiconductor wafers, apparently the process does not represent a high temperature fusion bond process. Moreover, since the formation of pressure sensors is described, it may be assumed that CMOS specific methods for high integration densities, high values for reliability and production yield, may not be advantageously used. Any defects that may be present in the homogeneous wafer material (Czochralski silicon) may prevent, for instance, the formation of gate oxides having a high quality.

On the other hand, from U.S. Pat. No. 5,295,395, it is known in the context of the description of the formation of membrane pressure sensors to use a first semiconductor wafer having an epitaxial layer of inverse doping, by means of which the semiconductor wafer is connected to a second semiconductor wafer by fusion bonding, with a subsequent thinning of the first semiconductor wafer down to the epitaxial layer in such a manner that the membrane is formed by the epitaxial layer. Any hint with respect to a subsequent formation of any signal processing electronic circuitry on the surface of the epitaxial layer is not given. Rather, one may learn from the patent document that after the wafer bonding, no further high temperature step is appropriate, since a fill material is required in the recesses to avoid the deformation of wafer portions of the cap wafer above the recesses during the wafer bond process, wherein the fill material is removed in a later stage.

In the known publications, there is no hint that the electronic part of the sensors and the signal processing electronics in the form of highly integrated circuitries may be monolithically integrally formed on the basis of the same manufacturing technique.

### BRIEF SUMMARY OF THE DRAWINGS

FIG. 1 is an example of a wafer composite formed by a bulk wafer 2 and an EPI-wafer 1, which are connected by means of a high temperature silicon fusion bonding technique so as to form a wafer composite.

FIG. 2 is an example of an absolute pressure sensor using the wafer composite of FIG. 1.

### DETAILED DESCRIPTION OF THE INVENTION

MEMS devices have been manufactured for years on the basis of silicon technologies. Initially, sensor elements have been denoted as MEMS devices, which are composed of a micromechanical portion and a microelectronic portion. The production methods may be divided into two categories according to their micromechanical configuration. On the one hand, a silicon wafer is processed in its total vertical dimension, i.e., it is processed into its depth direction to manufacture structures for the detection of mechanical entities, such as pressure and acceleration (bulk micromachining technologies). On the other hand, such structures are only created at the surface of the silicon wafer (surface micromachining technologies). The method according to the present invention represents a combination of both types of technologies.

While initially the sensors for the detection of mechanical parameters and the signal processing electronics (for instance, digital integrated circuits) have been provided as separate entities, the advance in technology calls for the monolithic integration of both components. The integration of micromechanical sensors and electronic circuits in a single chip is demanding with respect to the manufacturing technology, since the manufacturing processes for the sensors are frequently not compatible with the highly integrated CMOS technologies having feature sizes of ≦1μ. A compromise with respect to achievable performance characteristics (sensitivity, precision, measurement range), integration (feature sizes), reliability and manufacturing cost is necessary.

The specific methodology known for the part of the micromechanical sensors of MEMS devices comprises the patterning of a cavity body, frequently a cavity wafer, by well-established semiconductor process steps, such as oxidation, photolithography, and wet chemical etch processes. In this way, recesses or depressions are etched into the silicon, which are formed into cavities by covering the same in a later manufacturing stage, wherein the silicon membrane or any other sensor elements that are moveable upon mechanical stress are located above the cavities. After the patterning of the cavity body, it is non-separably bonded to a top cap wafer by means of a wafer bond technique with that side that has formed therein the recesses, so that cavities are formed around the recesses. Thereafter, the wafer stack formed in this manner is processed by silicon grinding and polishing processes, as are well-established in semiconductor processing, thereby significantly thinning the top cap wafer.

DE-A 199 27 970 and DE-A 199 27 971 disclose an intermediate layer deposited on one of the two semiconductor wafers for the formation of cavities. Recesses (depressions) are then formed in the intermediate layer. By means of the intermediate layer, the semiconductor wafer is bonded to a second semiconductor wafer. Thereafter, one of the two semiconductor wafers is thinned to a thickness corresponding to the thickness of the membrane, thereby forming a membrane above the cavity. Since in these instances, the electronic structure is formed in the homogeneously doped wafer material, and since the wafers are connected by means of an intermediate layer formed on one of the semiconductor wafers, apparently the process does not represent a high temperature fusion bond process. Moreover, since the formation of pressure sensors is described, it may be assumed that CMOS specific methods for high integration densities, high values for reliability and production yield, may not be advantageously used. Any defects that may be present in the homogeneous wafer material (Czochralski silicon) may prevent, for instance, the formation of gate oxides having a high quality.

On the other hand, from U.S. Pat. No. 5,295,395, it is known in the context of the description of the formation of membrane pressure sensors to use a first semiconductor wafer having an epitaxial layer of inverse doping, by means of which the semiconductor wafer is connected to a second semiconductor wafer by fusion bonding, with a subsequent thinning of the first semiconductor wafer down to the epitaxial layer in such a manner that the membrane is formed by the epitaxial layer. Any hint with respect to a subsequent formation of any signal processing electronic circuitry on the surface of the epitaxial layer is not given. Rather, one may learn from the patent document that after the wafer bonding, no further high temperature step is appropriate, since a fill material is required in the recesses to avoid the deformation of wafer portions of the cap wafer above the recesses during the wafer bond process, wherein the fill material is removed in a later stage.

In the known publications, there is no hint that the electronic part of the sensors and the signal processing electronics in the form of highly integrated circuitries may be monolithically integrally formed on the basis of the same manufacturing technique.

It is the object of the present invention to increase the sensitivity and the reliability, as well as to decrease the production costs and application costs, of MEMS devices having integrated evaluation electronics. Moreover, an improvement of the production method should be accomplished, so that the sensor-specific portion and the portion of the evaluation electronics of the MEMS device, which is based on CMOS technology, may be manufactured monolithically in a common technology.

The requirements for the application of a CMOS technology may be fulfilled by providing the specifications of the wafer material of the cap wafer and, in particular, that of the epitaxial layer (dopant, sheet resistance, defect structure) formed on the wafer, wherein the epitaxial layer may specifically have the thickness of the desired membrane, as well as by using high temperature fusion bonding techniques for bonding two semiconductor wafers.

It is within the scope of the present invention that electronic structures may be incorporated into the epitaxial layer of the cap wafer even prior to the wafer bonding process, wherein the electronic structures are configured in such a way that they may not significantly be altered by the subsequent high temperature treatment, or the electronic structure may be completed thereby, thus contributing to a densification of the electronic structures or/and contributing to a performance improvement.

### EXAMPLES

The subject matter of this invention is now described with reference to the following Examples. These Examples are provided for the purpose of illustration only, and the subject matter is not limited to these Examples, but rather encompasses all variations which are evident as a result of the teaching provided herein.

### Example 1

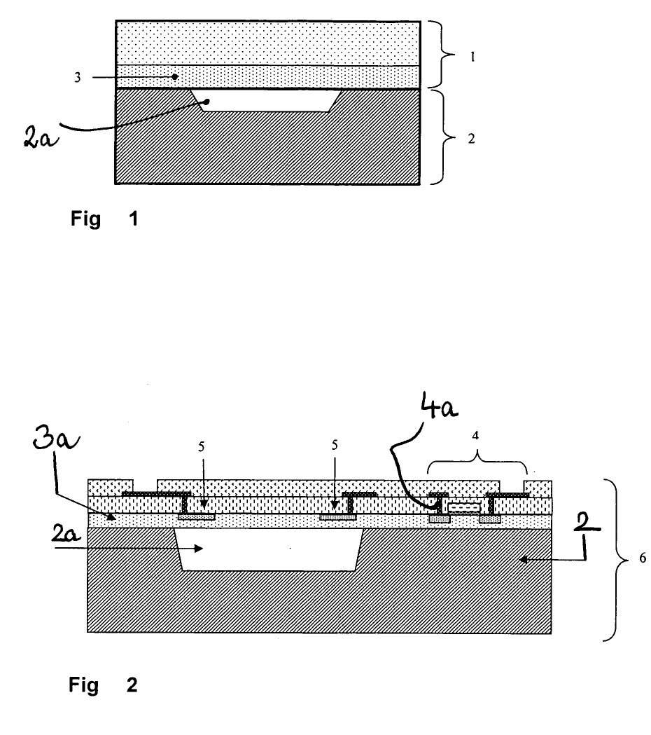

FIG. 1 shows the bonding of two semiconductor wafers, in the present case, silicon wafers, which are not configured in the same way. They serve the purpose for manufacturing microelectromechanical sensors, wherein the sensors and the signal processing electronics are monolithically integrally formed. The first wafer 2 is configured as a silicon wafer. The wafer has formed therein a cavity 2a. Also, a plurality of cavities may be provided, wherein for illustrative purposes, a single cavity is illustrated in a magnified manner as a part of a larger wafer. The EPI-wafer carries a substrate formed from silicon and an epitaxal layer, which is denoted as 3. These two wafers 1 and 2 are firmly connected by high temperature fusion bonding via the epitaxial layer 3, i.e., its surface. The recess or cavity 2a is covered and forms a closed cavity.

The wafer composite consisting of both wafers is shown in FIG. 2 in a further advanced manufacturing stage. The wafer composite has been thinned or reduced from the second wafer 1 down to the epitaxial layer 3. The residual 3a (residual thickness) of the remaining epitaxial layer 3 may be seen from FIG. 2 and covers the cavity 2a, thereby forming a cavity 2a (closed or sealed cavity).

The thinning or material reduction is performed to a thickness that corresponds to a thickness of the membrane so as to pick up measurement signals by mechanical deformation of this membrane. The thickness of the remaining membrane 3a corresponds to the micromechanical portion of a sensor 5, which in FIG. 2 is schematically illustrated as a pressure sensor. The pressure sensors 5 are located above the cavity 2a (i.e., they are registered with respect to the cavity). The thinning may be performed to obtain any other different thickness corresponding to a thickness of any other portion of the semiconductor wafer responding to a mechanical stress, wherein such a portion is not shown.

Subsequently, a polishing step is performed, which is not explicitly shown. After the polishing process, an electronic sensor structure 4 registered with respect to the cavity is formed on the polished surface in a common process along with one or more analogous and/or one or more digital circuitries by means of an appropriate technology process, in the example shown, a CMOS technology, in order to form the entire SOS wafer 6, which may be considered as a wafer stack. The sensors 5 are located in the remaining EPI-layer 3a. The circuit elements 4 are located on the remaining EPI-layer and exhibit normal electrical characteristics.

The method results in a reliable overall process having a high yield, which is appropriate for mass production.

The incorporation of structures of electronic circuitries in the epitaxial layer may also be performed prior to the bonding process of the wafers (prior to the bonding) according to FIG. 1 (not explicitly illustrated).

The EPI-layer 3 may then have incorporated therein structures of the electronic circuitries on that side that faces the cavity 2a for forming the closed cavity after the connection (also not explicitly shown). The electronic structures on the side facing the cavity 2a may, at least after the bonding of the wafers, extend to the polished side (i.e., the surface) and, thus, may, for instance, form electrically conductive channels, which are not explicitly shown.

On the side facing the cavity 2a shall mean that the corresponding electronic structures are formed at least partially in the layer, i.e., in the membrane 3a or at least extend thereto.

The side facing the cavity 2a has, due to said electronic structures, at least one sensor which is not shown, and which is appropriate for the analysis of a medium located adjacent to a membrane 3a in the cavity 2a.

The general methodology, which is referred to with respect to the formation of the electronic sensor structures 4, may not be explicitly described, since these processes are generally known as CMOS technology methods.

A method is described for forming a microelectromechanical system (MEMS), which comprises the monolithical integration of the sensor and the sensor signal processing electronics on the basis of CMOS technologies. By bonding of a semiconductor wafer 2 having a recess with a wafer having formed thereon an epitaxial layer by means of a high temperature fusion bonding technique via the epitaxial layer 3 so as to form a double wafer, and by a subsequent reduction of the double wafer followed by a polishing process, until the epitaxial layer is exposed, thereby creating a membrane 3a, the prerequisites are given so as to realize the electronic portion 4 of the sensor 5 and the signal processing electronics by means of CMOS technology methods.

1. A method for forming microelectromechanical sensors (MEMS), wherein the sensors and the sensor signal processing electronics are monolithically integrated, comprising
(i) firmly connecting a first silicon wafer having cavities formed thereon with a second cap wafer having an epitaxial layer by means of high temperature fusion bonding via the epitaxial layer,
(ii) wherein the wafer composite is reduced from the second wafer towards the epitaxial layer, that is, to a membrane thickness corresponding to the micromechanical portion of the sensor or to a thickness of another portion of the semiconductor wafer responding to mechanical stress, and wherein the wafer composite is finally polished,
(iii) wherein after the polishing process, the electronic sensor structures registered to the cavity are commonly formed along with the analogous or/and digital circuitries on the polished surface by means of CMOS technology methods.

2. The method of claim 1, characterized in that prior to the wafer bonding process, structures of electronic circuitries are already on that side of the epitaxial layer that faces the cavity after the bonding process.

3. The method of 1, characterized in that the electronic structures formed on the side facing the cavity at least after the wafer bonding process extend to the polished side to form, for instance, electronically conductive channels.

4. The method of claim 1, wherein the electronic structures created at the side facing the cavity comprise specific sensors in particular for the analysis of the medium located adjacent to the membrane in the cavity.

5. A method for forming a microelectromecanical sensor or system (MEMS), wherein at least one sensor and an associated sensor processing electronic are monolithically integrally formed,
(i) by bonding a first wafer comprising at least one cavity with a second wafer carrying an epitaxial layer by means of a high temperature fusion bonding process via the epitaxial layer to form a composite of the wafers;
(ii) wherein the composite of the wafers is thinned from the second wafer down to the epitaxial layer and is (finally) polished;
(iii) wherein after the polishing process at least one sensor structure aligned to the cavity and at least one analogous or/and digital circuit on the polished surface are formed by means of a CMOS technology method.

6. The method of claim 5, wherein thinning is performed according to a membrane thickness corresponding to the micromechanical portion of the sensor or according to a thickness of another portion of the semiconductor wafer that is sensitive or responsive to a mechanical stress.

7. The method of claim 5, wherein prior to the wafer bonding process electronic circuits are already formed on or aligned to the side which after the bonding of the wafers faces the cavity or covers the cavity.

8. The method of claim 5, wherein the electronic structures formed on the side facing the cavity extend, at least after the wafer bonding process, to the polished side and on particular form electrically conductive channels.

9. The method of claim 5, wherein the electronic structures located at the side facing the cavity comprise sensors for the analysis of a medium located adjacent to the membrane in the cavity.

10. A micromechanical sensor or system (MEMS), wherein at least one sensor and associated sensor signal processing electronics are monolithically integrally formed,
(i) by bonding the first wafer comprising at least one cavity to a second wafer carrying an epitaxial layer by means of a high temperature fusion bonding process via the epitaxial layer so as to form a composite of the wafers;
(ii) by reducing the composite of the wafers from the second wafer down to the epitaxial layer and by polishing the same;
(iii) wherein a mechanical sensor structure is aligned to the cavity and is commonly provided with an analogous or/and digital circuit on the polished surface at least partially in the thinned epitaxial layer, formed prior to or after the polishing process by means of a monolithic integrating technology method.

11. The sensor of claim 10, wherein the thinning is performed to obtain the thickness of a membrane.

12. The sensor of claim 10, wherein the circuit structure is provided prior to or during the bonding.

13. The sensor of claim 10, wherein the technology method is a CMOS technique.
